(19) United States
(12) Patent Application Publication
(10) Pub. No.: US 2007/0041439 A1
(43) Pub. Date: Feb. 22, 2007

(54) Filtering method and an apparatus

(76) Inventors: Radu Bilcu, Tampere (FI); Pauli Kuosmanen, Kangasala (FI); Karen Egiazarian, Tampere (FI)

Correspondence Address: WARE FRESSOLA VAN DER SLUYS &;ADOLPHSON, LLP, BRADFORD GREEN, BUILDING 5, 755 MAIN STREET, P O BOX 224, MONROE, CT, 06468, US

(21) Appl. No.: 10/554,042

(22) PCT Filed: Apr. 22, 2004
(86) PCT No.: PCT/FI04/50045

§ 371 Date: Oct. 20, 2005

(30) Foreign Application Priority Data
Apr. 22, 2003 (FI) 20035050

(51) Int. Cl. H03K 5/159; H04B 1/10; H04L 7/00

(52) U.S. Cl. 375/232; 375/350; 375/355

(57) ABSTRACT

The invention relates to a method for filtering. In the method an adaptive filtering is performed to an input signal. The filtered signal is further interpolated. The input signal is also interpolated for adapting the adaptive filtering. In the method the properties of the interpolation of the filtered signal are adaptable. The invention also relates to an apparatus comprising an adaptive filter for filtering an input signal, a first interpolator for interpolating the filtered signal, and a second interpolator for interpolating the input signal. The interpolated input signal is used to adapt the adaptive filter. The apparatus further comprises a first adapting block for adapting the properties of the first interpolator.

### FIELD OF THE INVENTION

The present invention relates to a method for filtering comprising adaptive filtering an input signal, interpolating the filtered signal, interpolating the input signal for adapting the adaptive filtering, providing a reference signal, combining the interpolated filtered signal and the reference signal for forming an error signal. The invention also relates to an apparatus comprising an adaptive filter for filtering an input signal, a first interpolator for interpolating the filtered signal, a second interpolator for interpolating the input signal, wherein the interpolated input signal is arranged to be used to adapt the adaptive filter.

### BACKGROUND OF THE INVENTION

In prior art there are many different filter designs for different signal filtering purposes. The filters can be divided into different categories e.g. on the basis of the impulse response of the filters. The filters can have either infinite impulse response (IIR) or finite impulse response (FIR). The filters can further be categorised into sub categories on the basis of other properties of the filters. In this patent application the finite impulse response filters, or FIR filters, are considered in greater detail.

The finite impulse response of the FIR filters means that if an impulse is input to the FIR filter the output of the FIR filter will stabilize to zero or to a constant value in course of time. In other words, the effect of the input impulse to the output of the FIR filter is finite in time.

In the following, some terms typical to filters are defined. The filters typically have a certain frequency response. This means that different frequency components of the input signal are attenuated or amplified differently, i.e. the frequency properties of the input signal affect on how the signal passes through the filter. For example, filters having low-pass frequency response attenuate high frequency signals more than low frequency signals. High-pass filters attenuate low frequency signals more than high frequency signals. Band pass filters have a certain, band pass frequency region on which signals are attenuated less than signals outside the band pass frequency region. Band stop filters have a certain, band stop frequency region on which signals are attenuated more than signals outside the band pass frequency region. The frequency on which the filtering properties change (e.g. from stop band to pass band or vice versa) is called as a cut off frequency. Typically the cut off frequency is defined as a frequency on which the attenuation of the filter is 3 dB above the minimum attenuation (or amplification is 3 dB below maximum amplification) of the pass band of the filter. In band pass filters there are two cut off frequencies defined, wherein the pass band lies between the lower cut off frequency and the upper cut off frequency. It should be noted here that in practical implementations the filtering properties does not change suddenly at the cut off frequency but there is always a transition region in which the attenuation (or amplification) properties of the filter changes. It is also obvious that the frequency response is not necessarily constant on the pass band or on the stop band but there can exist some variations (ripple) as is known by an expert in the field.

There are many ways to implement apparatuses containing FIR filters. In some designs adaptivity has been achieved by using some adaptive blocks in the filtering apparatus. As an example of such a filtering apparatus an adaptive interpolated FIR filter, or AIFIR filter for short, is presented in the following. AIFIR filters, which contain one or more interpolators, are applicable in such applications in which a large adaptive FIR filter is required. For example, in echo cancellation, there is a necessity to use a large FIR adaptive filter to model the echo path. When an AIFIR filter is used in a filtering apparatus, this gives an important reduction of the arithmetic operations for both filtering and weight updating. The AIFIR filters are well known by an expert in the field. It should be noted that the interpolator plays an important role in the performance of these structures. The existing approaches in the field of AIFIR filtering apparatuses does not deal with the design of the interpolator. There are many applications, such as system identification and channel equalization, in which prior information about the frequency response of the system to be modelled is not available. Therefore, in these applications it is not possible to design a fixed interpolator.

The U.S. Pat. No. 5,966,415 discloses a digital filter structure comprising an equalizer followed by an interpolator. The equalizer works at a lower sampling rate while at the output of the interpolator the signal has a higher sampling rate. The filter comprises a coefficient register file for storing different sets of coefficients for the interpolator. Based on the data clock and the sampling rate interpolation interval corresponding coefficients are taken from the coefficient register file to be used for the interpolation. The values of the coefficients stored in the coefficient register file are computed in advance by using well known methods such as the minimum mean square error between the interpolator frequency response and the ideal frequency response. Therefore, the coefficients are not adaptive but are computed in advance.

The block diagram of one prior art apparatus including an AIFIR filter is presented in FIG. 1, where W(n) represent the sparse FIR adaptive filter having (L−1) zeros between non-zero coefficients. The block denoted by i represents the interpolation filter with fixed coefficients which recreates the removed samples from W(n), x(n) is the input signal, d(n) is the desired signal, z(n) is the output noise and e(n) is the output error. The filtering structure is composed by a cascade of two FIR filters. The goal is to estimate the desired signal d(n) based on the input signal x(n). The coefficients of the adaptive sparse filter W(n) are adapted such that the expected value of the squared error is minimized. In order to handle the sparse nature of the filter W(n) a constrained approach has to be used. Therefore, the constrained cost function to be minimized is the following:
Minimize E[e²(n)], (1)
Subject to C^{T}W=f (2)

Taking into account (1) and (2) the adaptive constrained LMS algorithm used for adaptation of the sparse FIR filter W(n) can be described as follows:

First, the output of the filter W(n) is computed by:
y(n)=W^{t}(n)X(n), (3)
where X(n) [x(n), x(n−1), . . . , x(n−N+1)]^{t} is the vector of the past N samples from the input signal x(n) and N is the length of the adaptive filter W(n).

Second, the output of the interpolator is computed:
Yᵢ(n)=I^{t}Y(n), (4)
where I=[i₁, i₂, . . . , i_{M}]^{t} is the vector containing the interpolator coefficients and Y(n)=[y(n), y(n−1), . . . , y(n−M+1)]^{t} is the vector of the past M samples from the signal y(n).

Then, the output error is computed:
e(n)=d(n)+z(n)−yₜ(n), (5)

The filtered input vector X_{I}(n) is computed as follows:

$${X}_{I} ( n ) = {\sum }_{j = 0}^{M - 1} {i}_{j} X ( n - j ) \qquad ( 6 )$$

When all the above calculations are performed, the sparse adaptive filter weights can be updated:
W(n+1)=F{W(n)+μe(n)X_{I}(n)}+q (7)
where F=I_{d}−C^{t}(CC^{t})⁻¹C is the projection matrix, I_{d} is the identity matrix of the order of N, and q=C^{t}(CC^{t})⁻¹f is a correction vector.

The matrix C and the vector f from the constrained condition (2) in the case of AIFIR are given by (for N odd and L=2):

$$\begin{matrix}C = {[ \begin{matrix}0 & 1 & 0 & 0 & 0 & ⋯ & 0 & 0 & 0 \\ 0 & 0 & 0 & 1 & 0 & ⋯ & 0 & 0 & 0 \\ ⋮ & ⋮ & ⋮ & ⋮ & ⋮ & ⋰ & ⋮ & ⋮ & ⋮ \\ 0 & 0 & 0 & 0 & 0 & ⋯ & 0 & 1 & 0\end{matrix} ]}_{K \times N} & ( 8 ) \\ f = {[ \begin{matrix}0 & ⋯ & 0\end{matrix} ]}_{1 \times K}^{t} = {0}_{K \times 1} & ( 9 )\end{matrix}$$

where

$$K = [ \frac{N}{L} ]$$

is the number of zero coefficients in the sparse filter W(n) and [*] represents the integer part of the quantity inside the brackets.

Taking into account the equations (8) and (9), the matrix F and the vector g in the Equation (7) can be written as follows:

$$\begin{matrix}F = {[ \begin{matrix}1 & 0 & 0 & 0 & 0 & ⋮ & 0 \\ 0 & 0 & 0 & 0 & 0 & ⋮ & 0 \\ 0 & 0 & 1 & 0 & 0 & ⋮ & 0 \\ 0 & 0 & 0 & 0 & 0 & ⋮ & 0 \\ ⋮ & ⋮ & ⋮ & ⋮ & ⋮ & ⋰ & ⋮\end{matrix} ]}_{N \times N} & ( 10 ) \\ q = {[ \begin{matrix}0 & ⋯ & 0\end{matrix} ]}_{1 \times N}^{t} & ( 11 )\end{matrix}$$

According to the Equations (10) and (11), it can be seen that the Equation (7) is equivalent with the update equation of the standard LMS, in which just N−K coefficients are adapted provided that the vector W(n) is initialised with zeros. Therefore, the multiplication with F and the addition of q does not introduce extra computations in the Equation (7).

It is also easy to conduct matrices for other values than L=2. For example, if L=3 the matrix F has the following contents:

$$F = {[ \begin{matrix}1 & 0 & 0 & 0 & 0 & ⋮ & 0 \\ 0 & 0 & 0 & 0 & 0 & ⋮ & 0 \\ 0 & 0 & 0 & 0 & 0 & ⋮ & 0 \\ 0 & 0 & 0 & 1 & 0 & ⋮ & 0 \\ 0 & 0 & 0 & 0 & 0 & ⋮ & 0 \\ ⋮ & ⋮ & ⋮ & ⋮ & ⋮ & ⋰ & ⋮\end{matrix} ]}_{N \times N}$$

The matrix F has non-zero values (=1) only on the main diagonal so that every Lth value of the main diagonal is non-zero.

It is well known that in the case of an interpolated FIR filter the interpolator has to be designed in order to remove the frequency images introduced by the zero taps on the sparse filter W(n). In all prior art publications known by the applicant of the present invention in the field of AIFIR filters the interpolator has fixed coefficients and the filter is designed based on some available information about the system to be identified, i.e. optimal filter properties.

In order to illustrate how the prior art AIFIR filter approaches work, two possible practical example implementations are described. In the first implementation the AIFIR filter is used to identify a low-pass filter, and in the second implementation the AIFIR filter is used to identify a high-pass filter. In both implementations the fixed interpolator has a low-pass filter frequency response, because it is assumed that the optimum filter interpolator is unknown and there is no information available for designing the interpolator. Therefore, a low-pass frequency response is assumed in these examples.

The frequency response of the optimum filtering apparatus of the first implementation is presented in FIG. 2, and the frequency response of the AIFIR filtering apparatus according to the first implementation is depicted in FIG. 3. Respectively, the frequency response of the optimum filtering apparatus of the second implementation is presented in FIG. 4, and the frequency response of the AIFIR filtering apparatus according to the second implementation is depicted in FIG. 5. Now, when the FIGS. 2 and 3 are compared, it can be seen that the prior art AIFIR filter works quite well, in the case when the frequency response of the interpolator is appropriately chosen (for example, a low-pass interpolator for a low-pass optimum filter). In the case when the design of the frequency response of the interpolator does not match the frequency response of the optimum filtering apparatus (for example, a low-pass interpolator for a high-pass optimum filter) the prior art AIFIR filter totally fails as can be seen when comparing the FIGS. 4 and 5.

### SUMMARY OF THE INVENTION

The aim of the present invention is to provide an improved method for filtering signals, and an apparatus comprising an adaptive filter in which less computation power is needed compared with prior art filtering apparatuses. The invention is based on the idea that at least one interpolator of the apparatus is adaptive, wherein the coefficients of the interpolator can be changed according to the desired frequency characteristics of the apparatus. The adaptation can be performed, for example, by using the normalized least mean square (NLMS) algorithm. To put it more precisely, the method according to the present invention is mainly characterized by that the properties of the interpolation of the filtered signal are adaptable. The apparatus according to the present invention is mainly characterized by that the apparatus further comprises a first adapting block for adapting the properties of the first interpolator.

Significant advantages are achieved with the present invention. In applications where a very large FIR filter is required, the complexity of the apparatus can be reduced due to the fact that a small number of coefficients are different from zero. Therefore, less calculation operations are needed than with prior art filtering apparatuses. The invention is also applicable with applications in which there it is not possible to have information about the frequency response of an optimum filtering apparatus. Therefore, by using the method of the present invention the frequency characteristics of the apparatus can be adjusted according to the desired frequency response. Also, when there is a need to change the frequency response of the apparatus during operation it is possible with the apparatus of the present invention. The memory space needed to store the filter coefficients is also smaller than with prior art FIR filters.

### DESCRIPTION OF THE DRAWINGS

In the following, the invention will be described in more detail with reference to the appended drawings, in which

FIG. 1 depicts one prior art AIFIR filtering apparatus as a block diagram,

FIG. 2 depicts the frequency response of the optimum filter of a first example situation,

FIG. 3 depicts the frequency response of a prior art AIFIR filter for the first example situation,

FIG. 4 depicts the frequency response of the optimum filter of a second example situation,

FIG. 5 depicts the frequency response of a prior art AIFIR filter for the second example situation,

FIG. 6 depicts an apparatus according to an advantageous embodiment of the present invention as a block diagram,

FIG. 7 depicts the frequency response of the apparatus of FIG. 6 in the first example situation,

FIG. 8 depicts the frequency response of the apparatus of FIG. 6 in the second example situation, and

FIGS. 9a to 9d depict some of main applications classes as simplified block diagrams.

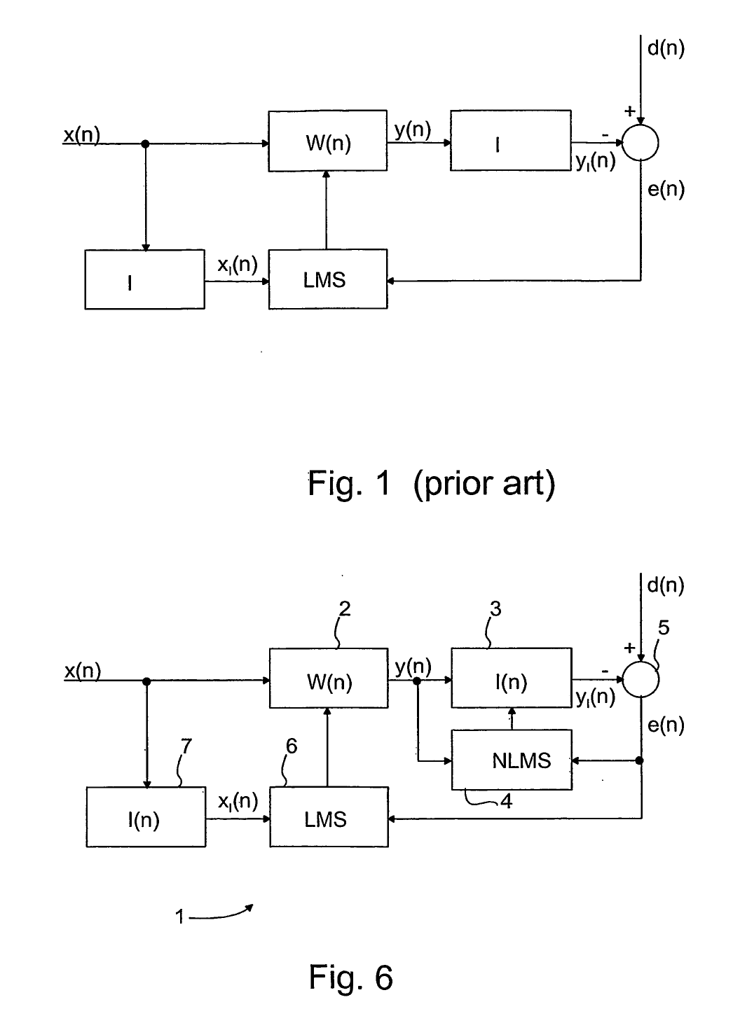

### DETAILED DESCRIPTION OF THE INVENTION

In FIG. 6 there is presented a block diagram of an apparatus 1 according to an advantageous embodiment of the present invention. The apparatus 1 includes a signal processing block having an adjustable interpolator. The signal processing block is advantageously an adaptive FIR filter 2 in which the input signal x(n) is filtered. Hence, the apparatus 1 according to this advantageous embodiment of the present invention can also called as an AIFIR filtering apparatus. It is obvious that also other signal processing blocks than FIR filters can be used with the present invention. For example, infinite impulse response filters (IIR) can be used in some applications. The output signal y(n) of the adaptive FIR filter 2 is directed to a first adaptive interpolator 3 and to a first adapting block 4. The interpolated signal is directed from the output of the first adaptive interpolator 3 to the first input 5.1 of a combiner 5. The second input 5.2 of the combiner 5 receives a reference signal d(n)+z(n), which consists of the desired signal d(n) and noise z(n). The combiner 5 subtracts the output signal from the reference signal of the first adaptive interpolator 3 to form an error signal e(n). The error signal e(n) is directed to the first adapting block 4 and to a second adapting block 6. The first adapting block 4 uses the error signal e(n) and the output signal y(n) of the adaptive FIR filter 2 to form adapting information for the first adaptive interpolator 3. The first adapting block 4 uses the adapting information to change the properties of the first adaptive interpolator 3 when necessary, for example, by changing one or more coefficients of the adaptive interpolator 3. The apparatus of FIG. 6 also comprises a second adaptive interpolator 7 which receives the input signal x(n) and interpolates it to form an interpolated input signal x_{I}(n). This is necessary in order to have signals with substantially same sample rate at both inputs of the second adapting block 6. In addition to the error signal e(n), the second adapting block 6 also receives the interpolated input signal x_{I}(n). The second adapting block 6 uses the received signals e(n), X_{I}(n) to change the properties of the adaptive FIR filter 2 when necessary.

In the following, the operation of the individual blocks of the apparatus 1 will be described in more detail. The adaptive FIR filter 2 is sparse FIR adaptive filter having (L−1) zeros between non-zero coefficients. The coefficients of the adaptive FIR filter 2 are preferably adapted such that the expected value of the squared error is minimized. In order to handle the sparse nature of the adaptive FIR filter 2 a constrained approach has to be used. The constrained cost function to be minimized is the same as with prior art filters. Therefore equations (1) and (2) are applicable here. Then, the similar steps than with prior art can be applied as follows:

First, the output of the adaptive FIR filter 2 is computed by equation (3):
y(n)=W^{t}(n)X(n).

Second, the output of the first adaptive interpolator 3 is computed by equation (4):
Y_{I}(n)=I^{t}(n)Y(n),
but now, the coefficients of the first adaptive interpolator 3 are also adapted. The adaptation is performed, for example, by using the following equation:

$$I ( n + 1 ) = I ( n ) + \frac{{μ}_{I}}{ɛ + {Y}^{t} ( n ) Y ( n )} e ( n ) Y ( n ) \qquad ( 8 )$$

where μ_{I} is the step-size used to adapt the coefficients of the interpolator, e(n) is the output error, I(n)=[i(n)₁, i(n)₂, . . . , i(n)_{M}]^{t} is the M×1 vector containing the coefficients of the interpolator, Y(n)=[y(n), y(n−1), . . . , y(n−M+1)]^{t} is the vector of the past M samples from the signal y(n), and ε is a small constant.

The output error e(n) is computed by using the equation (5):
e(n)=d(n)+z(n)−yₜ(n).

The filtered input vector Xₜ(n) is computed by using the equation (6):

$${X}_{I} ( n ) = {\sum }_{j = 0}^{M - 1} {i}_{j} X ( n - j ) .$$

When all the above calculations are performed, the sparse adaptive filter weights can be updated by using the equation (7):
W(n+1)=F{W(n)+μe(n)X_{I}(n)}+q.

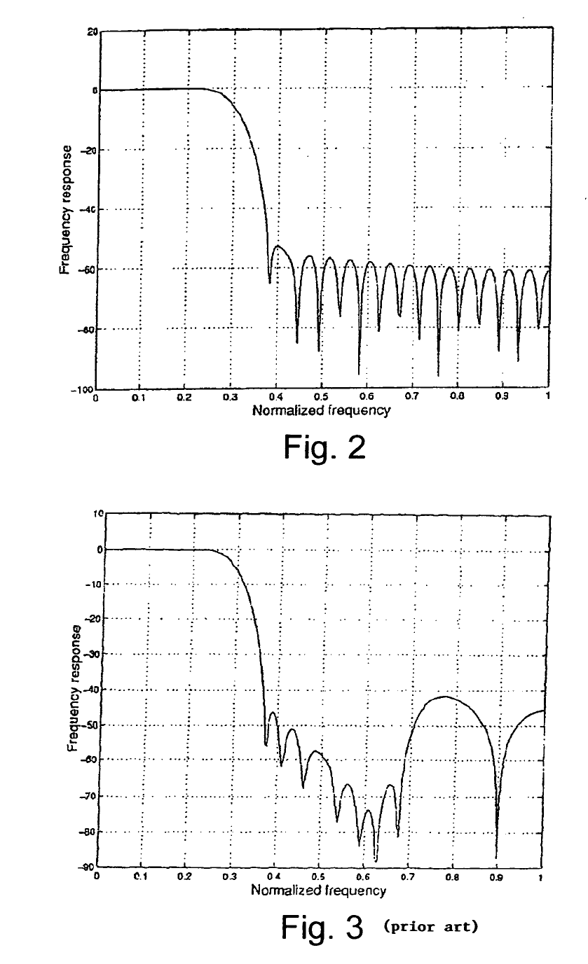

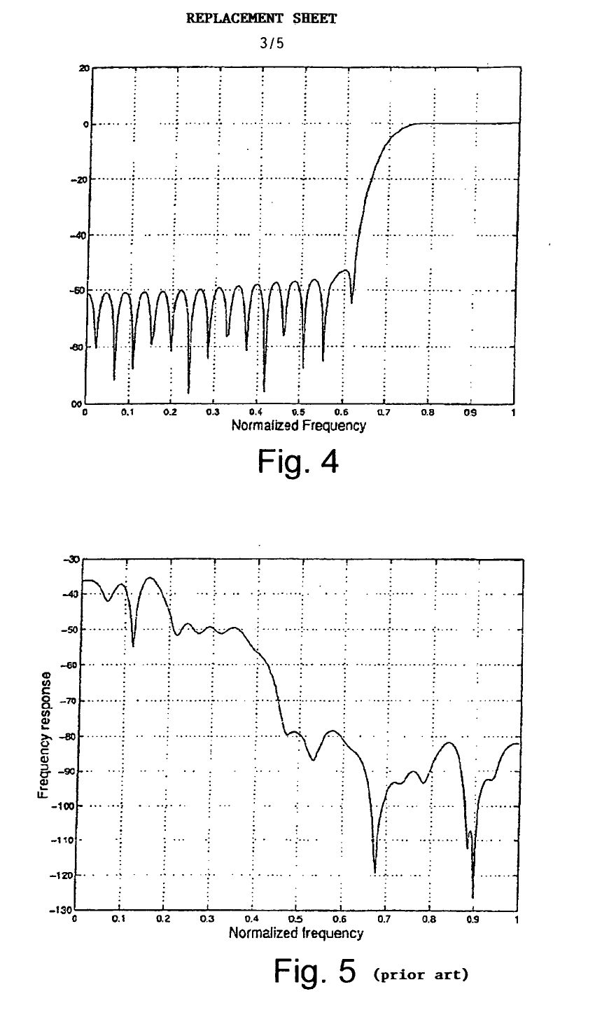

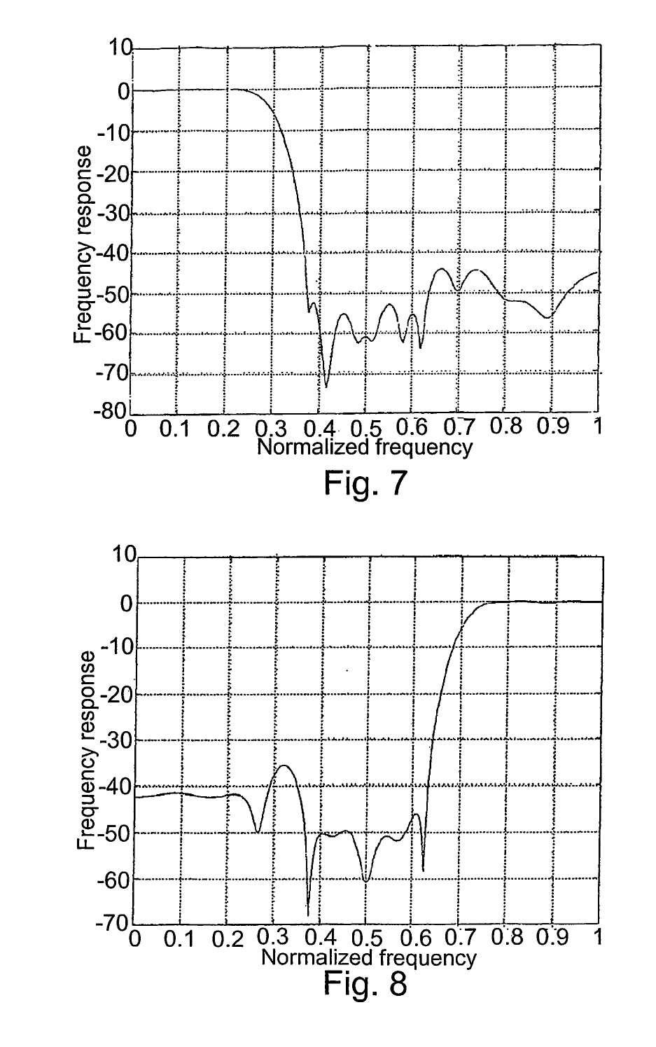

The behaviour of the apparatus according to the present invention can be analysed e.g. by using the similar example situations than what was used above in the description where the background art was considered. The frequency response of the optimum filtering apparatus for the first example is depicted in FIG. 2 and the respective frequency response of the apparatus 1 according to the present invention is depicted in FIG. 7. The frequency response of the optimum filtering apparatus for the second example is depicted in FIG. 4 and the respective frequency response of the apparatus 1 according to the present invention is depicted in FIG. 8. It can be seen by comparing the FIGS. 2, 3 and 7 that the filtering apparatus 1 according to the present inventions works substantially as well as the prior art filtering apparatus designed properly according to the requirements of the special situation. In that case, both the prior art filtering apparatus and the filtering apparatus of the present invention approximate very well the optimum filter.

In the case when the interpolator of the prior art filtering apparatus is not designed appropriately, the prior art filtering apparatus fails to find optimal coefficients for the adaptive FIR filter. The filtering apparatus 1 according to the present invention has also in this case a very good performance. This can be seen by comparing the FIGS. 4, 5 and 8.

Although the apparatus of FIG. 6 comprises the first 3 and the second adaptive interpolators 7, it is obvious that they can be implemented as a single functional unit or a piece of code of a digital signal processor (not shown). If, however, there are two adaptive interpolators 3, 7, they both can (and should) still use the same coefficients. Therefore, there is no need to store the coefficients for the adaptive interpolators 3, 7 twice. This also reduces the memory requirements of the apparatus 1.

The first adapting block 4 and the second adapting block 6 can use least mean square based (LMS) algorithms in adapting the coefficients of the interpolators 3, 7, respectively. However, the invention is not limited to LMS algorithms but also other suitable algorithms can be used in the coefficient adaptation.

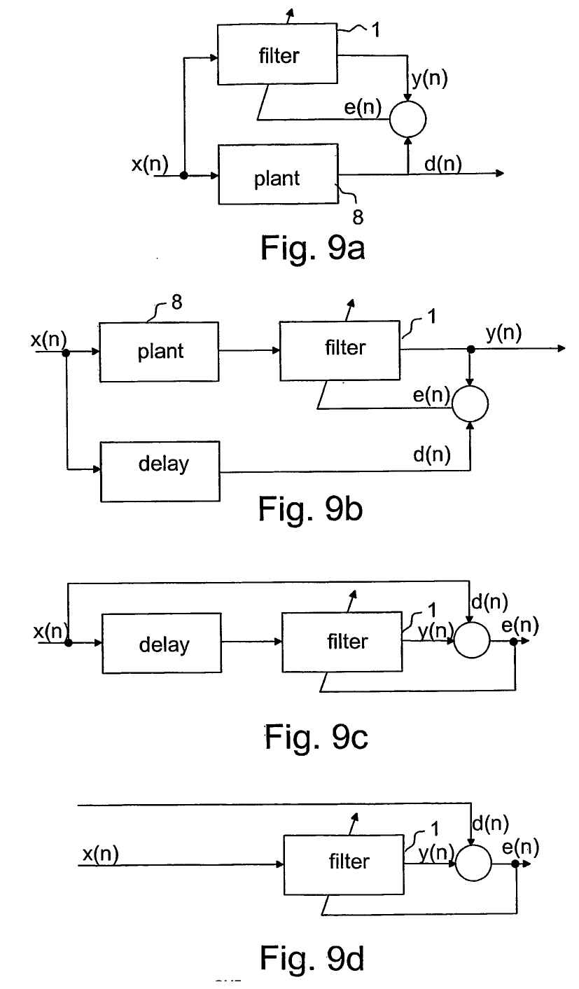

There are many application areas in which the filter according to the present invention can be applied. FIGS. 9a to 9d depict some of the main applications classes as simplified block diagrams. FIG. 9a depicts how the apparatus of the present invention comprising double adaptive interpolating FIR filter (DAIFIR) can be used in identification applications. The notion of a mathematical model is fundamental to sciences and engineering. Applications dealing with identification the filtering apparatus 1 is used to provide a linear model that represents the best fit to an unknown plant. The plant 8 and the filtering apparatus 1 are provided with the same input signal x(n). The plant output supplies the desired response d(n) for the filtering apparatus 1. If the plant is dynamic in nature, the model will be time varying.

FIG. 9b depicts an inverse modelling application. In this class of applications, the function of the adaptive filtering apparatus is to provide an inverse model that represents the best fit to an unknown noisy plant. Ideally, in the case of a linear system, the inverse model has a transfer function equal to the reciprocal of the plant's transfer function, such that the combination of the two constitutes an ideal transmission medium. A delayed version of the plant input constitutes the desired response for the filtering apparatus 1. In some applications the plant input can be used without delay as the desired response.

FIG. 9c depicts a predictive application. The function of the adaptive filtering apparatus is to provide the best prediction of the present value of a certain signal. The present value of the signal thus serves the purpose of a desired response for the adaptive filtering apparatus. Past values of the signal supply the input applied to the filtering apparatus 1. Depending on the application of interest, the output y(n) of the filtering apparatus or the estimation error e(n) may serve as the system output. In the first case, the system operates as a predictor, in the latter case, it operates as a prediction-error filter.

The fourth class of applications is interference modelling and it is depicted in FIG. 9d as a simplified block diagram. In this class of applications, the filtering apparatus 1 is used to cancel unknown interference contained in primary signal, with the cancellation being optimised in some sense. The primary signal serves as the desired response for the filtering apparatus 1. A reference signal is employed as the input to the adaptive filtering apparatus. The reference signal is derived from a sensor or set of sensors located in relation to the sensor(s) supplying the primary signal in such a way that the information-bearing signal component is weak or essentially undetectable.

The above described application classes are known by an expert in the field of adaptive filters. The present invention provides improved filtering method to be applied e.g. in those application areas. The improvements are mainly based on the adapting nature of the interpolators, which has not been used with prior art filtering methods.

The above mentioned filtering applications can be utilized, for example, in analysing properties of systems such as buildings, earth, human body, communication channels, etc. For example, in the case of analysing buildings the input signal can be a shock wave, wherein the filter coefficients can be used in evaluating the behaviour of the building during earthquakes.

The filtering method of the present invention can also be used for noise cancellation e.g. to suppress maternal ECG component in fetal ECG. The input signal x(n) of the filtering apparatus 1 is taken near the mother's heart to generate as clean heartbeat signal as possible of the mother's heartbeats. The desired signal d(n) is taken near the abdominal of the mother to get a fetal ECG signal. The “error” signal e(n) of the filtering apparatus 1 is then the fetal ECG signal from which the mother's heartbeat signal is substantially totally removed.

It is also possible to use the filtering method of the present invention in channel equalization, time delay estimation, echo cancellation, adaptive control etc. It is obvious that the above mentioned applications are just non-restrictive examples in which the present invention can be applied.

1. A method for filtering comprising adaptive filtering an input signal, interpolating a filtered signal, interpolating the input signal for adapting the adaptive filtering, and adapting properties of an interpolation of the filtered signal.

2. The method according to claim 1 comprising providing a reference signal, and combining an interpolated filtered signal and the reference signal for forming an error signal.

3. The method according to claim 2 comprising adapting the properties of the interpolation according to the error signal and the interpolated filtered signal.

4. The method according to claim 2 comprising adapting the properties of the interpolation by changing at least one coefficient of the interpolation.

5. The method according to claim 4 comprising adapting the at least one coefficient of the interpolation by using a normalized least mean square algorithm, wherein the method further comprises using the error signal and the interpolated filtered signal as inputs for the algorithm.

6. The method according to claim 2 comprising:
a) computing the filtered signal by an equation
y(n)=W^{t}(n)X(n);
b) computing the interpolated filtered signal by an equation
Y_{I}(n)=I^{t}(n)Y(n);
c) adapting interpolation coefficients of an interpolator by an equation
$$I ( n + 1 ) = I ( n ) + \frac{{μ}_{I}}{ɛ + {Y}^{t} ( n ) Y ( n )} e ( n ) Y ( n )$$
where μ_{I} is a step-size used to adapt the coefficients of the interpolator, e(n) is an output error, I(n)=[i(n)₁, i(n)₂, . . . , i(n)_{M}]^{t} is an M×1 vector containing the interpolation coefficients of the interpolator, Y(n)=[y(n), y(n−1), . . . , y(n−M+1)]^{t} is a vector of past M samples from the filtered signal y(n), and ε is a constant;
d) computing the output error e(n) by an equation
e(n)=d(n)+z(n)−y(n);
e) computing a filtered input vector X_{I}(n) by an equation
$${X}_{I} ( n ) = {\sum }_{j = 0}^{M - 1} {i}_{j} X ( n - j ) ;$$
$$and$$
f) updating filtering weights by an equation
W(n+1)=F{W(n)+μe(n)X_{I}(n)}+q.

7. The method according to claim 1 comprising using finite impulse response filtering in said adaptive filtering.

8. An apparatus comprising
an adaptive filter for filtering an input signal;
a first interpolator for interpolating a filtered signal;
a second interpolator for interpolating the input signal, wherein an interpolated input signal is arranged to be used to adapt the adaptive filter; and
a first adapting block for adapting the properties of the first interpolator.

9. The apparatus according to claim 8 also comprising an input for receiving a reference signal, and a combiner for combining an interpolated filtered signal and the reference signal for forming an error signal.

10. The apparatus according to claim 9, wherein the properties are arranged to be adapted according to the error signal and an interpolated filtered signal.

11. The apparatus according to claim 9, wherein the first adapting block is adapted to change at least one coefficient of the first interpolator.

12. The apparatus according to claim 11, wherein the first adapting block is adapted to use a normalized least mean square algorithm to adapt the at least one coefficient of the first interpolator, wherein the error signal and the interpolated filtered signal are arranged to be used as inputs for the algorithm.

13. The apparatus according to claim 8, also comprising a second adapting block for adapting properties of the adaptive filter.

14. The apparatus according to claim 8, wherein said adaptive filter is a FIR filter.
